(19) United States
(12) Patent Application Publication
(10) Pub. No.: US 2005/0156323 A1
(43) Pub. Date: Jul. 21, 2005

(54) Semiconductor apparatus

(75) Inventor: Shinya Tokunaga, Kyoto (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/022,967

(22) Filed: Dec. 28, 2004

(30) Foreign Application Priority Data
Jan. 8, 2004 (JP) P. 2004-002747

(51) Int. Cl. H01L 23/58

(52) U.S. Cl. 257/778

(57) ABSTRACT

In case that a size of an upper layer semiconductor chip is larger than a lower layer semiconductor chip, a semiconductor chip is packed without damaging it.

In a semiconductor apparatus in which a second semiconductor chip 103 is laminated on a first semiconductor chip 102, and accommodated in one package, at least one side among four sides which configure an outer edge of the second semiconductor chip 103 is configured in such a manner that it is larger than four sides which configure an outer edge of the first semiconductor chip 102, and thereby, a protruding portion which is protruded from the outer edge of the first semiconductor chip 102 is provided, and a convex supporting part 110 is provided on a surface of a circuit substrate 101 on which the first semiconductor chip 102 and the second semiconductor chip 103 are laminated, and the protruding portion is configured in such a manner that it can be supported by the convex supporting part 110.

### BACKGROUND OF THE INVENTION

1. Field of the Invention

This invention relates to a semiconductor apparatus of such a type that a plurality of semiconductor chips are laminated and accommodated in one package, and in particular, relates to a semiconductor apparatus in such a case that a first stage semiconductor chip is disposed in a face-down manner, and a second stage or later chip is larger than a lower stage chip.

2. Description of the Related Art

A conventional supporting part at the time when a second chip is larger than a first chip, is manufactured by use of an under-fill of the first chip, at the periphery of the first chip, and by use of resin of the under-fill (e.g., see, JP-A-2000-299431 publication (Pages 1-10, FIG. 1)).

Also, there is also such a thing that, at the periphery of the first chip, a table member is mounted on a circuit substrate by an adhesive agent (e.g., see, JP-A-2001-320014 publication (Pages 1-5, FIG. 1)).

In case that a plurality of semiconductor chips are laminated and accommodated in one package, and in case that a size of a second stage semiconductor chip, at least one side thereof is larger than a first stage semiconductor chip (the configuration of FIG. 1), the following points become problems.

From requests of increase of the number of laminated chips and miniaturization of a semiconductor apparatus, based upon recent advances in semiconductor technologies, it is further requested that a thickness of a semiconductor chip gets thinner than in the past. On this account, a semiconductor chip becomes weaker more and more in resistance characteristics to manufacturing damages.

If a second stage semiconductor chip, an outside dimension of which is larger than a first stage semiconductor chip, is laminated on the first stage semiconductor chip in a face-up state, a wire bonding pad of the second semiconductor chip is necessarily located more outside than the first semiconductor chip, in a protruding part of the second semiconductor chip.

In this state, if the second semiconductor chip is wire-bonded, heating of the second stage semiconductor chip is difficult, and also, impact shock (ultrasonic load) at the time of bonding is concentrated on the protruding portion of the second semiconductor chip, with which a corner part of the first semiconductor chip is in contact, so that there is such a case that the second semiconductor chip is broken down.

Also, only the first stage semiconductor chip can be connected to a circuit substrate in a face-down state, and the second stage or later semiconductor chip is connected to the circuit substrate by wire bonding, and therefore, they are necessarily laminated in a face-up state. In this state, a limiting condition is generated as to an order of laminating, depending on a size of a semiconductor chip to be laminated.

### SUMMARY OF THE INVENTION

This invention is a thing which was made in view of the suchlike problems, and intends to provide a semiconductor apparatus which can carry out wire bonding without damaging a semiconductor chip, even in case that a size of an upper layer semiconductor chip, at least one side thereof is larger than a lower semiconductor chip, and mitigated the restriction of the laminating order of semiconductor chips.

In order to accomplish the above-described object, in invention according to a preferred embodiment, a semiconductor apparatus comprises: a circuit substrate; a first semiconductor chip flip-chip-bonded on the circuit substrate; a second semiconductor chip laminated on the first semiconductor chip, the second semiconductor chip being connected to the circuit substrate by an electric conductive wire and being larger than the first semiconductor chip so that the second semiconductor chip is protruded from at least one side of the first semiconductor chip as a protruding portion; and a convex supporting part to support the protruding portion from bottom surface of the second semiconductor chip, the convex supporting part being integrated with the circuit substrate as one portion.

According to this embodiment, since the second semiconductor chip is supported by the convex supporting part integrated with the circuit substrate as one portion, in case of wire-bonding between the second semiconductor chip and the circuit substrate, it is possible to sufficiently transfer heat to the second semiconductor chip through the convex supporting part, and it is possible to carry out heating to the second semiconductor chip effectively. Also, it is possible to mitigate bonding impact shock which is added to the protruding portion protruding from at least one side of the first semiconductor chip. As a result of that, it is possible to prevent breakage of the second semiconductor chip. Moreover, since the convex supporting part and the circuit substrate are integrated as one portion, it is possible to easy to make the convex supporting part precisely employing a simple manufacturing method of the circuit substrate so that a manufacturing step to make a conventional supporting part employing a complicated manufacturing method with an under-fill is omitted to reduce a manufacturing cost of the semiconductor apparatus.

Also, an invention according to a preferred embodiment characterized in that the second semiconductor chip is protruded from all sides of the first semiconductor chip and the convex supporting part supports the protruding portion formed at the all sides of the second semiconductor chip.

According to this embodiment, since the second semiconductor chip is supported by the convex supporting part at the all sides of the second semiconductor chip, it is possible to mount the second semiconductor chip with securing more stability.

Also, an invention according to a preferred embodiment is characterized in that the convex supporting part supports outer edges of the second semiconductor chip.

According to this embodiment, since the second semiconductor chip is supported by the convex supporting part at outer edges of the second semiconductor chip, it is possible to mount the second semiconductor chip with securing more stability.

Also, an invention according to a preferred embodiment is characterized in that the convex supporting part supports a part of the protruding portion of the second semiconductor chip.

According to this embodiment, the convex supporting part on an upper surface of the circuit substrate is reduced, and it is possible to carry out improvement of easiness of filling of the sealing resin under the second semiconductor chip.

Also, an invention according to a preferred embodiment is characterized in that the semiconductor apparatus further comprises: a bonding electrode formed on the second semiconductor chip, the bonding electrode connected to the circuit substrate by the electric conductive wire, wherein the convex supporting part supports the protruding portion from bottom surface of the second semiconductor chip below the bonding electrode.

According to this embodiment, since the convex supporting part supports the second semiconductor chip just below the bonding electrode which receives bonding impact shock in case of wire-bonding between the second semiconductor chip and the circuit substrate, it is possible to mitigate bonding impact shock more easily. As a result of that, it is possible to prevent breakage of the second semiconductor chip more easily.

Also, an invention according to a preferred embodiment is characterized in that the second semiconductor chip has a protruding portion protruding from the first semiconductor by a certain value and the convex supporting part only supports the protruding portion protruding from the first semiconductor by the certain value.

According to this embodiment, since the protruding portion of the second semiconductor protruding from the first semiconductor chip less than the certain value is enough strongly supported by the first semiconductor chip, so the convex supporting part only supports the protruding portion protruding from the first semiconductor chip by the certain below. Therefore, manufacturing cost of the semiconductor apparatus is reduced.

Also, an invention according to a preferred embodiment is characterized in that a center of the second semiconductor chip is disposed with shifting a certain distance from a center of the first semiconductor chip.

According to this embodiment, the convex supporting part on an upper surface of the circuit substrate can be reduced, and a distance from an end of the shifted first semiconductor chip up to the convex supporting part on the upper surface of the circuit substrate that a bottom surface of the second semiconductor chip supports becomes large, and it is possible to carry out improvement of easiness of filling of the sealing resin all together.

Also, an invention according to 8th embodiment is characterized in that the second semiconductor chip has a protruding portion protruding from the first semiconductor by a certain value and the convex supporting part only supports the protruding portion protruding from the first semiconductor by the certain value.

Also, an invention according to a preferred embodiment is characterized in that the convex supporting part includes a plurality of columnar supporting parts and each of the plurality of columnar supporting parts supports the protruding portion.

According to this embodiment, since the second semiconductor chip is supported by the plurality of columnar supporting parts, on the occasion of filling sealing resin between the first semiconductor chip and the second semiconductor chip, the sealing resin is filled from gaps between any two adjacent pair of the plurality of columnar supporting parts, and therefore, filling of the sealing resin can be carried out easily.

Also, an invention according to a preferred embodiment is characterized in that the plurality of columnar supporting parts are disposed non-uniformly at a periphery of the second semiconductor chip.

According to this embodiment, since the plurality of columnar supporting parts being arranged non-uniformly supports the second semiconductor chip just below the bonding electrode which receives bonding impact shock in case of wire-bonding between the second semiconductor chip and the circuit substrate, it is possible to mitigate bonding impact shock more easily. As a result of that, it is possible to prevent breakage of the second semiconductor chip more easily.

Also, an invention according to a preferred embodiment is characterized in that columnar supporting parts of the plurality of columnar supporting parts are formed at even intervals along one side of the second semiconductor chip.

According to this embodiment, since the columnar supporting parts of the plurality of columnar supporting parts is arranged uniformly along one side of the second semiconductor chip, on the occasion of filling sealing resin between the first semiconductor chip and the second semiconductor chip, the sealing resin is filled from gaps between any two adjacent pair of the columnar supporting parts of the plurality of columnar supporting parts, and therefore, filling of the sealing resin can be carried out easily.

Also, an invention according to a preferred embodiment is characterized in that a reinforcing member is disposed at such a place that a distance between any adjacent ones of the plurality of columnar supporting parts is a certain distance or more.

According to this embodiment, since the reinforcing member is properly added to such a place that a distance between any two adjacent ones of the plurality of columnar supporting parts becomes a certain distance or more, and therefore, when the suchlike reinforced columnar supporting part is used as a seat of the second semiconductor chip, and a bottom surface of the protruded second semiconductor chip is supported, it is possible to mount the second semiconductor chip with ensuring stability.

Also, an invention according to a preferred embodiment is characterized in that the convex supporting part has a curved surface part on its upper end corner.

According to this embodiment, the curved surface part is formed on an upper end corner of the convex supporting part which is a seat of the second semiconductor chip, and therefore, stress concentration at the time of bonding impact shock, of the second semiconductor chip is avoided, and it is possible to mount the second semiconductor chip stably.

Also, an invention according to a preferred embodiment is characterized in that the convex supporting part has a curved surface part on its root part.

According to this embodiment, the curved surface part is formed on the root part of the convex supporting part which is a seat of the second semiconductor chip and the circuit substrate, and un-filling of sealing resin is prevented, and it is possible to mount the second semiconductor chip stably.

Also, an invention according to a preferred embodiment is characterized in that the convex supporting part is of a trapezoid, a width of which becomes narrower toward an upper part.

According to this embodiment, the convex supporting part which is a seat of the second semiconductor chip is made as a trapezoid shaped supporting part, a width of which becomes narrower toward a upper part, and therefore, it is possible to mount the second semiconductor chip more stably.

Also, an invention according to a preferred embodiment is characterized in that the semiconductor apparatus further comprises: a third semiconductor chip laminated on the second semiconductor chip, the third semiconductor chip being connected to the circuit substrate by a second electric conductive wire and being larger than the second semiconductor chip so that the third semiconductor chip is protruded from at least one side of the second semiconductor chip as a second protruding portion; a supporting part for supporting the second protruding portion from bottom surface of the third semiconductor chip, the supporting part being integrated with the circuit substrate as one portion.

According to this embodiment, even in a semiconductor apparatus of such a type that 3 or more of the semiconductor chips are laminated and accommodated in one package, it is possible to obtain operations and advantages of the above-described embodiments.

Also, in invention according to a preferred embodiment, a semiconductor apparatus comprises: a circuit substrate; a first semiconductor chip flip-chip-bonded on the circuit substrate; a second semiconductor chip laminated on the first semiconductor chip, the second semiconductor chip being connected to the circuit substrate through a projection electrode formed on a bottom surface of the second semiconductor chip and being larger than the first semiconductor chip so that the second semiconductor chip is protruded from at least one side of the first semiconductor chip as a protruding portion; a convex supporting part for supporting the protruding portion from bottom surface of the second semiconductor chip, the convex supporting part being integrated with the circuit substrate as one portion; a bump connection part formed on the convex supporting part, the bump connection part connected to the projection electrode; an extend terminal formed on a bottom surface to the circuit substrate; and an electric wiring connecting the projection electrode on the bottom surface of the second semiconductor chip to the external terminal through the bump connection part formed on the convex supporting part.

Also, an invention according to a preferred embodiment is characterized in that the electric wiring includes a wiring passing through an inside of the convex supporting part.

Also, an invention according to a preferred embodiment is characterized in that the electric wiring includes a wiring formed along a surface of the convex supporting part.

According to these embodiments, since the projection electrode of the second semiconductor chip and the external terminal of the circuit substrate are connected through the electric wiring and the bump connection part, therefore, wire-bonding to the second semiconductor chip becomes unnecessary, and chip restrictions at the time of mounting can be mitigated more.

### BRIEF DESCRIPTION OF THE DRAWINGS

FIG. 1 is a schematic cross-section view which shows a conventional semiconductor apparatus.

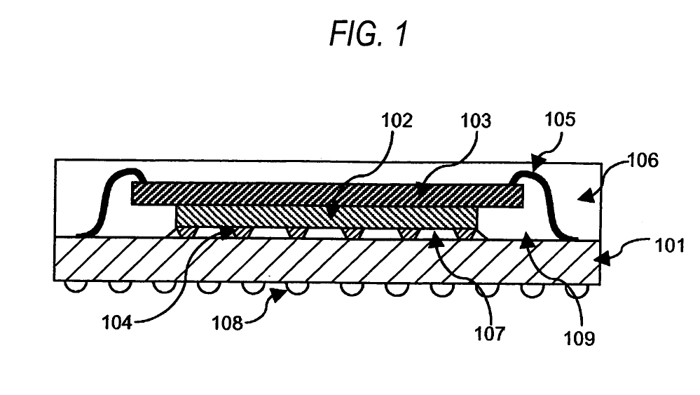

FIG. 2(a), (b) is a schematic cross-section view which shows a semiconductor apparatus of a first implementation mode of the invention.

FIG. 3(a), (b) is a schematic plan view which shows the semiconductor apparatus of the first implementation mode of the invention.

FIG. 4 is a schematic plan view which shows a semiconductor apparatus of a second implementation mode of the invention.

FIG. 5(a), (b) is a schematic plan view which shows a semiconductor apparatus of a third implementation mode of the invention.

FIG. 6 is a schematic plan view which shows a semiconductor apparatus of a fourth implementation mode of the invention.

FIG. 7(a), (b) is a schematic plan view which shows a semiconductor apparatus of a fifth implementation mode of the invention.

FIG. 8(a), (b) is a schematic plan view which shows a semiconductor apparatus of a modified example of the fifth implementation mode of the invention.

FIG. 9 is a schematic cross-section view which shows a semiconductor apparatus of a sixth implementation mode of the invention.

FIGS. 10(a), (b) is a schematic cross-section view which was viewed from a 201 direction of FIG. 9.

FIG. 11 is a schematic cross-section view which shows a semiconductor apparatus of a seventh implementation mode of the invention.

FIG. 12 is a schematic plan view which shows a semiconductor apparatus of an eighth implementation mode of the invention.

FIG. 13 is a substantial part cross-section view which shows the semiconductor apparatus of the eighth implementation mode of the invention.

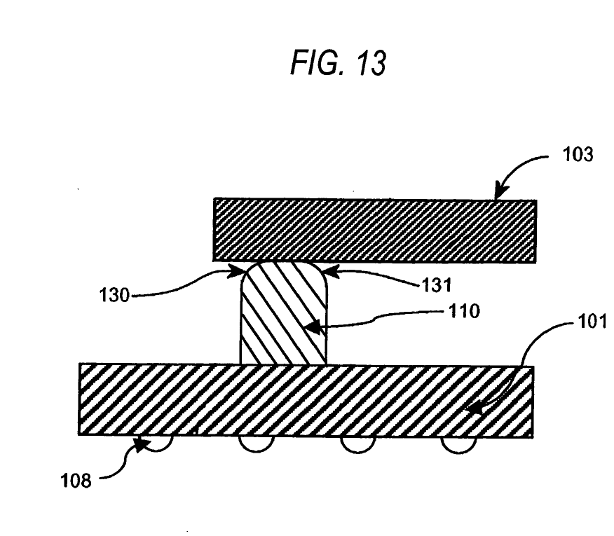

FIG. 14 is a substantial part cross-section view which shows a semiconductor apparatus of a ninth implementation mode of the invention.

FIG. 15 is a substantial part cross-section view which shows a semiconductor apparatus of a modified example of the ninth implementation

FIG. 16 is a substantial part cross-section view which shows a semiconductor apparatus of a modified example of the eight and ninth implementation modes of the invention.

FIG. 17 is a substantial part cross-section view which shows a semiconductor apparatus of a tenth implementation mode of the invention.

FIG. 18 is a substantial part cross-section view which shows a semiconductor apparatus of a modified example of the tenth implementation mode of the invention.

FIG. 19 is a schematic cross-section view which shows a semiconductor apparatus of an eleventh implementation mode of the invention.

FIG. 20 is a schematic cross-section view which shows the semiconductor apparatus of the eleventh implementation mode of the invention.

### DESCRIPTION OF THE PREFERRED EMBODIMENTS

Hereinafter, implementation modes of a semiconductor apparatus of the invention will be explained over referring to drawings.

(First Implementation Mode)

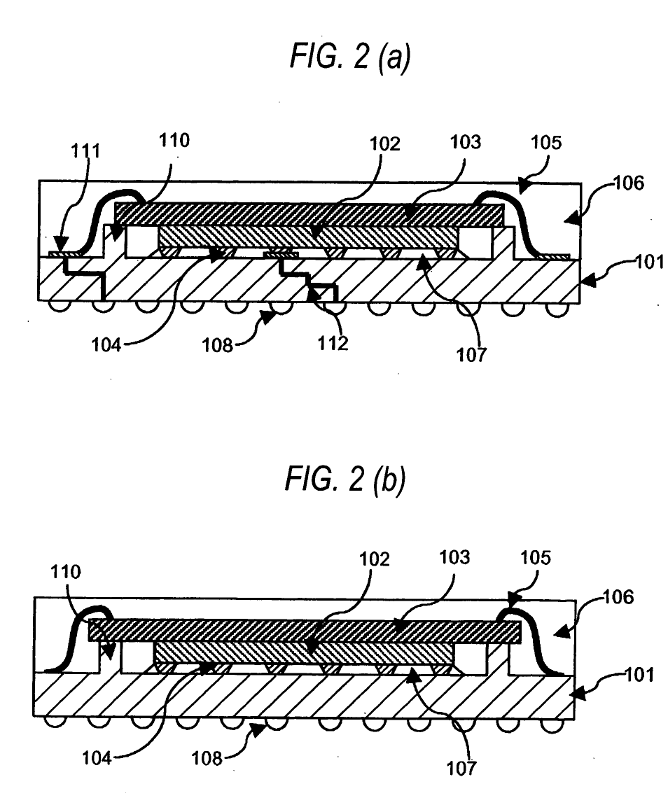

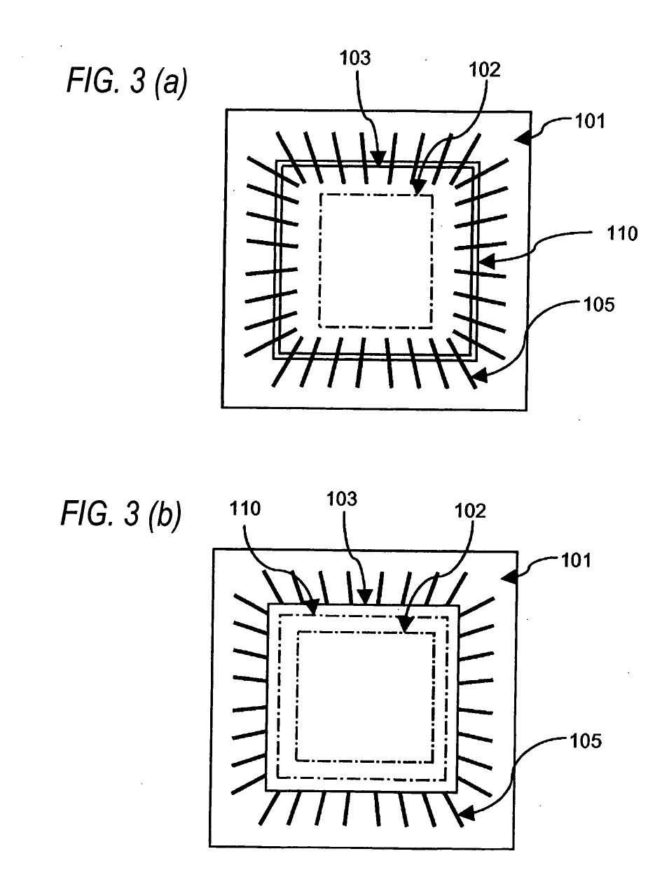

FIG. 2(a) is a schematic cross-section view of a semiconductor apparatus which relates to a first implementation mode of the invention, and FIG. 3(a) is its schematic plan view.

The semiconductor apparatus, which relates to the first implementation mode, is a semiconductor apparatus of such a type that two semiconductor chips were laminated and mounted in one package. Also, an upper side (second stage) second semiconductor chip 103 is larger in size than a lower side (first stage) first semiconductor chip, and at least a portion of the second semiconductor chip is protruded from one side of the first semiconductor chip.

Further, describing its configuration in detail, the semiconductor apparatus which relates to the first implementation mode is, as shown in FIG. 2(a), configured by an insulating circuit substrate 1011 which had a circuit wiring 111 on an upper surface, and external terminals 108 on a lower surface, which were connected to the circuit wiring 111 by via 112, a first semiconductor chip 102 which was mounted and connected to the circuit wiring 111 of the circuit substrate 101 through projection electrodes 104 such as gold bump electrodes to an upper surface of that circuit substrate 101, with such face-down that its projection electrode surface is placed downside, an under-fill material 107 which filled a gap between the first semiconductor chip 102 and the circuit substrate 101 and comprises insulating resin, a second semiconductor chip 103 which was laminated and mounted through adhesive paste (not shown in the figure) on the first semiconductor chip 102 with such a face-up that its main surface is placed upward, metal thin wires 105 which are electric conductive thin wires which electrically connect the circuit wiring 111 on the circuit substrate 101 and bonding electrodes (not shown in the figure) of the second semiconductor chip 103 by wire-bonding, and sealing resin 106 such as insulating epoxy resin, which sealed an area of the first semiconductor chip 102, the second semiconductor chip 103, and the metal thin wires 105 on an upper surface side of the circuit substrate 101, and a convex supporting part 110 is disposed on an upper surface of the circuit substrate 101, on an identical surface to an upper surface of the first semiconductor chip 102.

That is, in the semiconductor apparatus of this implementation mode, the convex_supporting part 110 on the upper surface of the circuit substrate 101 is formed so as to bridge with an outer circumference of the second semiconductor chip 103, and thereby, configured is a seat which receives a bottom surface of the second semiconductor chip 103.

The convex supporting part 110 is configured on the upper surface of the circuit substrate 101 such that the convex supporting part 110 and the circuit substrate 101 are integrated as one portion. The convex supporting part 110 supports a protruding portion of the second semiconductor chip 103 protruding from the first semiconductor chip 102 from bottom surface of the second semiconductor chip 103.

Also, the bonding electrodes on the main surface of the second semiconductor chips 103 are located on a chip outer circumference part, and the outer circumference part of the second semiconductor chip 103 is protruded from the first semiconductor chip 102 which was mounted on its lower side, and laminated, but by the seat which was configured by the convex supporting part 110 on the upper surface of the circuit substrate 101, a bottom surface of the protruded second semiconductor chip 103 is supported, and thereby, the second semiconductor chip 103 is mounted with ensuring stability.

Next, a schematic cross-section view of a modified example of the semiconductor apparatus of the first implementation mode is shown in FIG. 2(b), and its schematic plan view is shown in FIG. 3(b).

In this modified example, the convex_supporting part 110 on the upper surface of the circuit substrate 101 is formed so as to become an inside from the outer circumference part of the second semiconductor chip 103, and directly below the bonding electrodes of the second semiconductor chip 103, the bottom surface of the protruded second semiconductor chip 103 is supported by the seat which was configured by the convex supporting part 110 on the upper surface of the circuit substrate 101, and the second semiconductor chip 103 is mounted with ensuring stability.

With a size of a projection in which the outer circumference part of the second semiconductor chip 103 is protruded from the first semiconductor chip 102, judging from impact shock and heat transfer at the time of bonding, determined is a position of the seat where the convex supporting part 110 on the upper surface of the circuit substrate 101 supports the bottom surface of the second semiconductor chip 103.

(Second Implementation Mode)

Next, a second implementation mode of the invention will be explained.

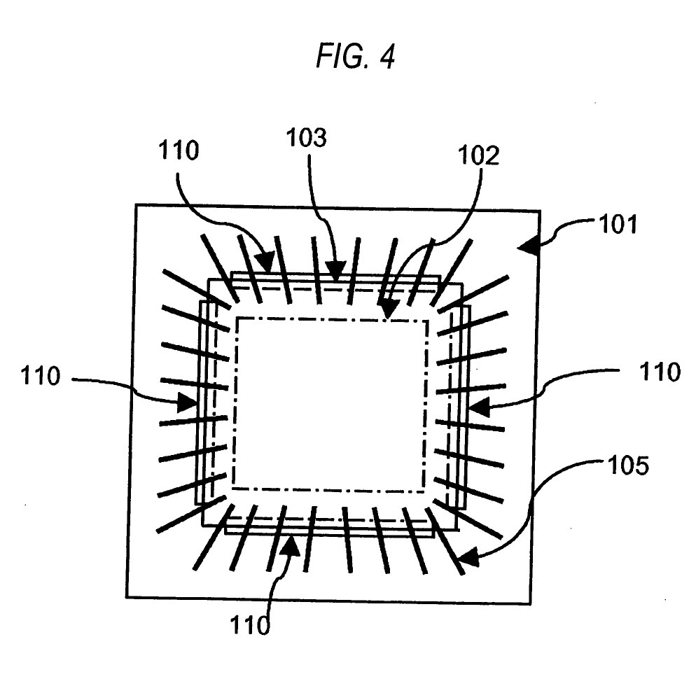

FIG. 4 is a schematic cross-section view of a semiconductor apparatus which relates to the second implementation mode. This implementation mode is an implementation mode of such a configuration that filling of the sealing resin 106 becomes easy.

The implementation mode is of a similar configuration to the first implementation mode, and hereinafter, only different points will be explained.

As shown in FIG. 4, in the implementation mode, the first semiconductor chip 102 is not surrounded by the convex supporting part 110 on the upper surface of the circuit substrate 101, as in the first implementation mode, but for the purpose of filling of the sealing resin 106 due to the gap between the first semiconductor chip 102 and the convex supporting part 110 on the upper surface of the circuit substrate 101, cut parts are disposed in four corners of the convex supporting part 110, and by this cut parts, the bottom surface of the protruding portion of the second semiconductor chip 103 is supported by seats of the convex supporting parts 110 which were configured independently in each side, and thereby, the second semiconductor chip 103 is mounted with ensuring stability. Meanwhile, the example of FIG. 4 showed such an example that cut parts are disposed in all four corners of the supporting part 110, but it would be fine if the cut part is disposed in at least one corner among the four corners. Also, as the cut part increases, filling of the sealing resin 106 becomes easier.

(Third Implementation Mode)

Next, a third implementation mode of the invention will be explained.

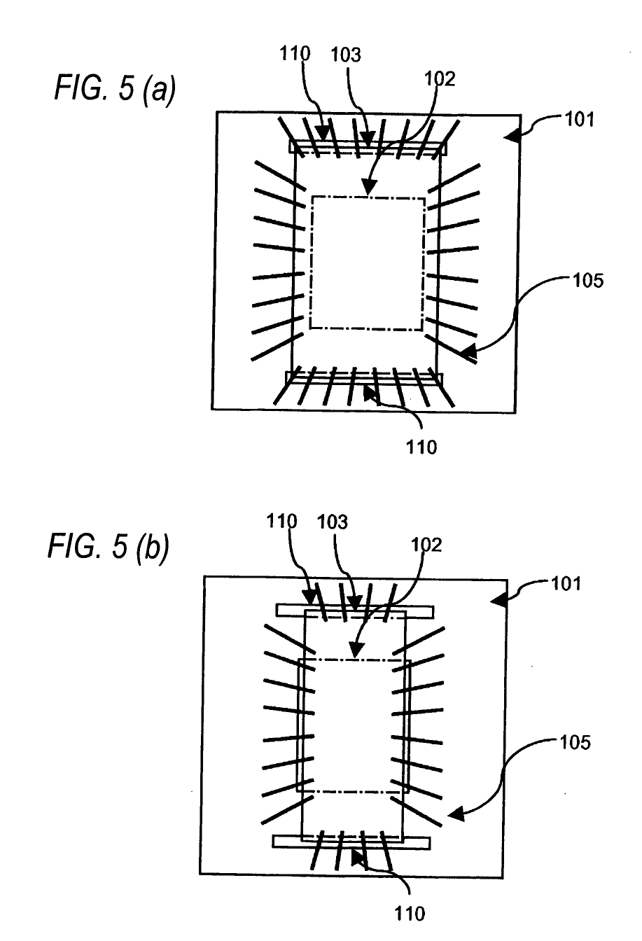

FIG. 5 is a schematic plan view of a semiconductor apparatus which relates to the third implementation mode.

In the semiconductor apparatus of this implementation mode, as shown in FIG. 5(a), the second semiconductor chip 103, in which only an outside dimension of one side is larger than an outside dimension of the first semiconductor chip 102, is laminated and mounted on the first semiconductor chip 102.

Further, the convex supporting parts 110 on the upper surface of the circuit substrate 101 are formed only on a side of the second semiconductor chip 103, an outside dimension of which is larger than the outside dimension of the first semiconductor chip 102.

The bottom surface of the protruding portion of the second semiconductor chip 103 is supported by the seats which were configured by the convex supporting parts 110 on the upper surface of the circuit substrate 101, an outside dimension of one side being larger than the outside dimension of the first semiconductor chip 102, and thereby, the second semiconductor chip 103 is mounted with ensuring stability.

A modified example of this implementation mode is shown in FIG. 5(b).

In the semiconductor apparatus of the modified example, as shown in FIG. 5(b), the second semiconductor chip 103 with the outside dimension which is larger than the outside dimension of the first semiconductor chip 102 is laminated and mounted on the first semiconductor chip 102.

At this time, when a size of projection of the second semiconductor chip 103 is less than a predetermined size, even if the bottom surface of the second semiconductor chip 103 is not supported, the second semiconductor chip 103 is mounted with ensuring stability.

Therefore, it would be fine if the convex supporting part 110 on the upper surface of the circuit substrate 101 is formed on only a side where the second semiconductor chip 103 is a predetermined size or more, and which is larger than the outside dimension of the first semiconductor chip 102.

In the example shown in FIG. 5(b), the second semiconductor chip 103 is protruded in a long side direction, the side being the predetermined size or more than the outside dimension of the first semiconductor chip 102, and bottom surfaces of two short sides of the protruding portion of the semiconductor chip 103 are supported by the seats which were configured by the convex supporting parts 110 on the upper surface of the circuit substrate 101, and the second semiconductor chip 103 is mounted with ensuring stability.

(Fourth Implementation Mode)

Next, a fourth implementation mode of the invention will be explained.

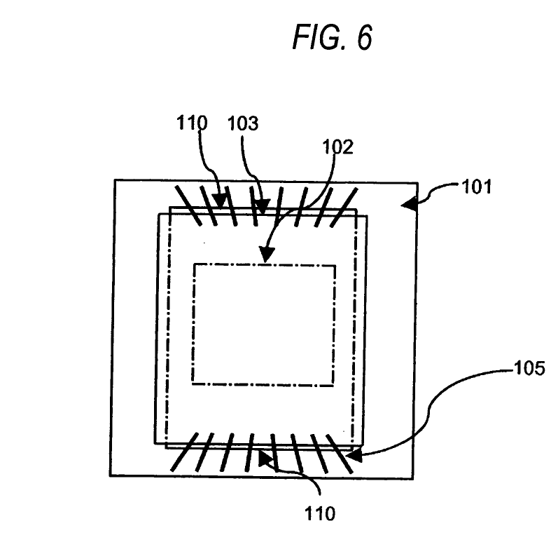

FIG. 6 is a schematic plan of a semiconductor apparatus which relates to the fourth implementation mode.

This implementation mode is of a similar configuration to the first implementation mode, and a position of formation of the convex supporting part 110 on the upper surface of the circuit substrate 101, which is its different portion, will be explained.

In the semiconductor apparatus of the implementation mode, as shown in FIG. 6, the second semiconductor chip 103 with an outside dimension which is larger than the outside dimension of the first semiconductor chip 102 is laminated and mounted on the first semiconductor chip 102.

As shown in FIG. 6, when the second semiconductor chip 103 is of such a chip configuration that the bonding electrode does not exist on at least one side, there is no necessity of supporting the bottom surface of the protruding portion of the second semiconductor chip 103 by the convex supporting part 110 on the upper surface of the circuit substrate 101, on a side where the bonding electrode does not exist, and therefore, the bottom surface of the protruding portion of the second semiconductor chip 103 is supported by the seat which was configured by the convex supporting part 110 on the upper surface of the circuit substrate 101, of the second semiconductor chip 103 on a side where the bonding electrode exists, and the second semiconductor chip 103 is mounted with ensuring stability.

Based upon recent rapid advances in semiconductor technologies, thin thickness and size growing of semiconductor chips progress, and therefore, the outside dimension of the second semiconductor chip 103 is much larger than the outside dimension of the first semiconductor chip 102, and there is such fear that the second semiconductor chip 103 bends down with its own weight, and in the suchlike case, particularly, an advantage of stability ensuring due to such a thing that the bottom surface of the protruding portion of the second semiconductor chip 103 is supported by the convex supporting parts 110 on the upper surface of the circuit substrate 101 is shown notably.

(Fifth Implementation Mode)

next, a fifth implementation mode of the invention will be explained.

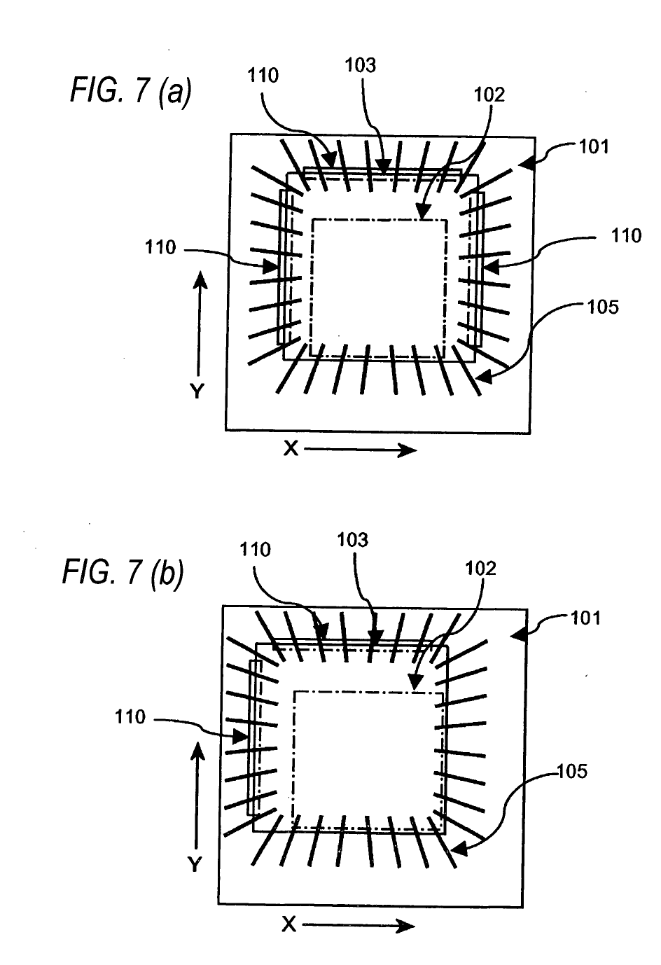

FIG. 7 is a schematic plan view of a semiconductor apparatus which relates to the fifth implementation mode.

It is of a configuration which is similar to the first implementation mode, and allocation of mounted chips and a position of formation of the supporting parts 110 on the surface of the circuit substrate 101, which are its different portions, will be explained.

In the semiconductor apparatus of the implementation mode, as shown in FIG. 7(a), the second semiconductor chip 103 with an outside dimension which is larger than the outside dimension of the first semiconductor chip 102 is laminated and mounted on the first semiconductor chip 102.

Further, the second semiconductor chip 103 is mounted with being shifted to a front side toward Y direction of FIG. 7(a) from a center of the first semiconductor chip 102.

An amount of the shift of the second semiconductor chip 103 is set to fall within such a range that a side on a rear side toward the Y direction of FIG. 7(a) can be stably mounted even if there is no seat which was configured by the supporting part 110 on the upper surface of the circuit substrate 101. The convex supporting part 110 on the upper surface of the circuit substrate 101 is reduced, and a distance from the first semiconductor chip 102 up to the convex supporting part 110 on the upper surface of the circuit substrate 101 that the bottom surface of the second semiconductor chip 103 supports becomes large on a side of a front side toward the Y direction of FIG. 7(a), and it is also possible to carry out improvement of easiness of filling of the sealing resin 106 all together.

Also, there is not any problem even if allocation of chips is shifted in both directions of X and Y as shown in FIG. 7(b).

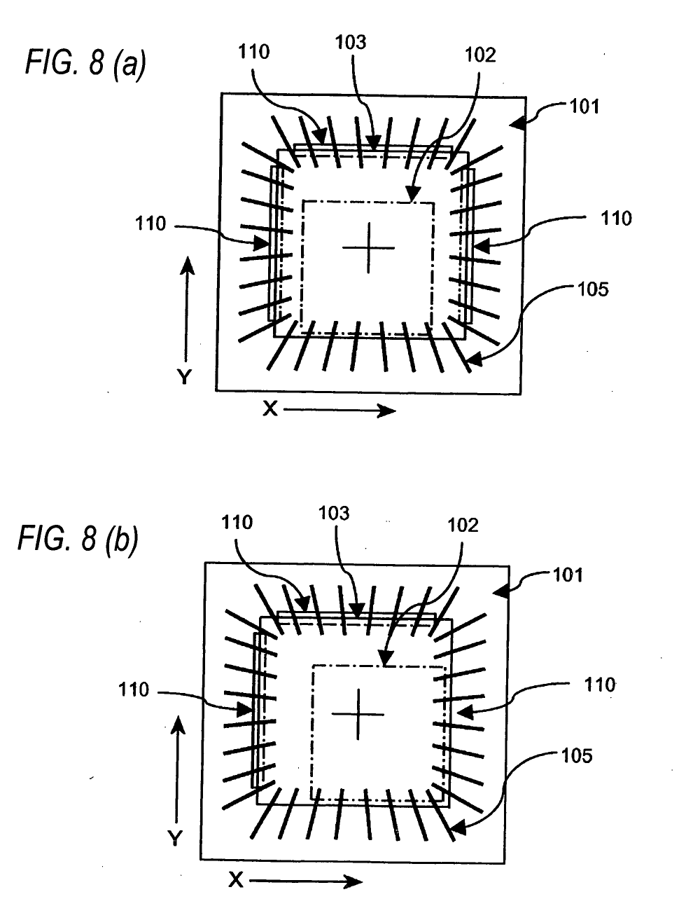

FIG. 8 is a schematic plan view which shows a modified example of the fifth implementation mode.

As shown in FIG. 8(a), the second semiconductor chip 103 with an outside dimension which is larger than the outside dimension of the first semiconductor chip 102 is disposed at a center of the circuit substrate 101, and the first semiconductor chip 102 is mounted by being shifted to a rear side toward Y direction of FIG. 8(a). An amount of the shift of the first semiconductor chip 102 is set to fall within such a range that a side on a rear side toward the Y direction of FIG. 8(a) can be stably mounted even if there is no seat which was configured by the convex supporting part 110 on the upper surface of the circuit substrate 101.

The convex supporting part 110 on the upper surface of the circuit substrate 101 is reduced, and a distance from an end of the first semiconductor chip 102 on a side of a front side toward the Y direction of FIG. 8(a) up to the convex supporting part 110 on the upper surface of the circuit substrate 101 that the bottom surface of the second semiconductor chip 103 supports becomes large, and it is also possible to carry out improvement of easiness of filling of the sealing resin 106 all together.

Also, there is not any problem even if allocation of chips is shifted in both directions of X and Y as shown in FIG. 8 (b).

(Sixth Implementation Mode)

Next, a sixth implementation mode of the invention will be explained.

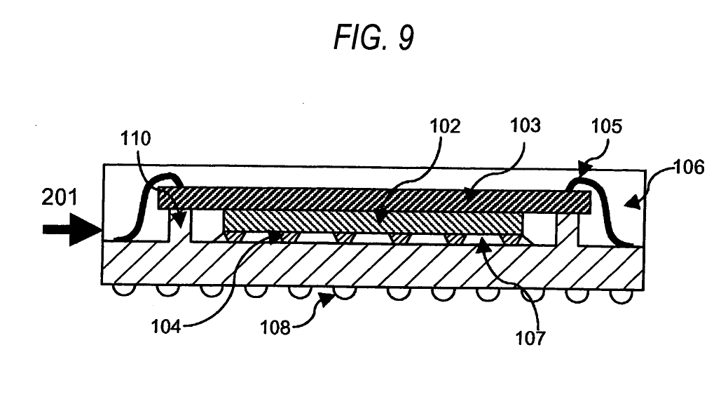

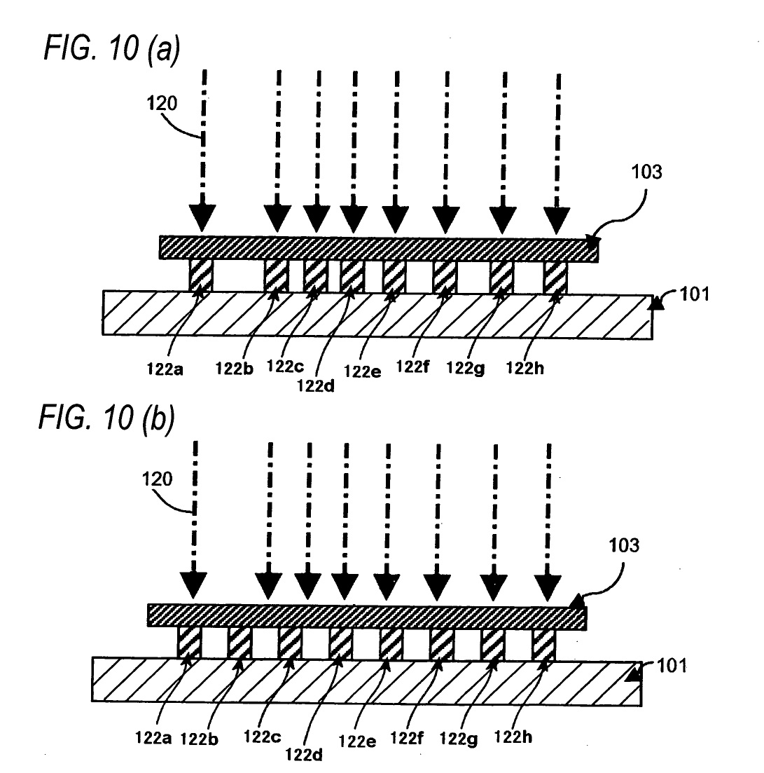

FIG. 9 is a schematic plan view of a semiconductor apparatus which relates to the sixth implementation mode, and FIG. 10 is a schematic cross-section view which was viewed from a direction of 201 of FIG. 9.

This implementation mode is of a similar configuration to the first implementation mode, and a shape of the convex supporting part 110 on the upper surface of the circuit substrate 101, which is its different portion, will be explained.

In the semiconductor apparatus of the implementation mode, as shown in FIG. 10(a), bonding electrodes 120 on the second semiconductor chip 103 are disposed non-uniformly at the periphery of the second semiconductor chip 103.

As the seat which supports the bottom surface of the second semiconductor chip 103, a plurality of columnar supporting parts 122 (122a˜122h) are formed so as to be located directly below the boding electrodes 120 on the second semiconductor chip 103, respectively.

In this manner, when the bottom surface of the protruding portion of the second semiconductor chip 103 is supported by the plurality of columnar supporting parts 122 (122a18 122h) which were formed directly below the bonding electrodes 120, respectively, as the seat of the second semiconductor chip 103, it is possible to mount the second semiconductor chip 103 with ensuring stability.

FIG. 10(b) is a schematic cross-section view which shows a modified example of the six implementation mode.

As shown in FIG. 10(b), the plurality of columnar supporting parts 122 (122a˜122h) are formed at even intervals, calculating from an protruding amount of the second semiconductor chip 103 and easiness of filling of the sealing resin 106, regardless of the bonding electrodes 120 on the second semiconductor chip 103.

This is for preventing a distance between the columnar supporting parts of FIG. 10(a) from becoming narrower than necessary, in case that a pitch of the bonding electrodes 120 is narrow.

In this manner, when the bottom surface of the protruding portion of the second semiconductor chip 103 is supported by the plurality of columnar supporting parts 122 which were formed at even intervals, as the seat of the second semiconductor chip 103, it is possible to mount the second semiconductor chip 103 with ensuring stability.

(Seventh Implementation Mode)

Next, a seventh implementation mode of the invention will be explained.

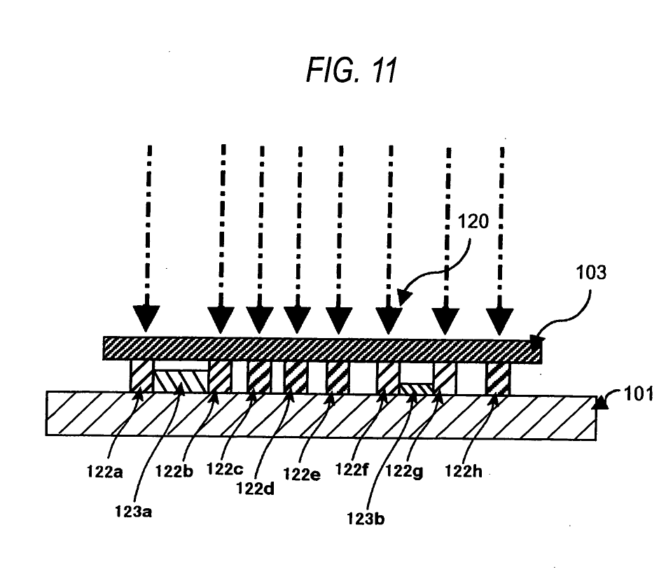

FIG. 11 is a schematic cross-section view of a semiconductor apparatus which relates to the seventh implementation mode, viewed from a direction of 201 of FIG. 9.

This implementation mode is of a similar configuration to the sixth implementation mode, and a shape of the convex supporting part 110 on the upper surface of the circuit substrate 101, which is its different portion, will be explained.

In the semiconductor apparatus of the implementation mode, as shown in FIG. 11, bonding electrodes 120 on the second semiconductor chip 103 are disposed non-uniformly at the periphery of the second semiconductor chip 103. As the seat which supports the bottom surface of the second semiconductor chip 103, a plurality of columnar supporting parts 122 (122a˜122h) are formed so as to be located directly below the boding electrodes 120 on the second semiconductor chip 103, respectively.

In this implementation mode, for the purpose of reinforcing strength of the columnar supporting parts 122, they are reinforced by properly adding reinforcing members between the columnar supporting parts.

A width of the reinforcing member is roughly the same as a width of the columnar supporting part 122, and a height of the reinforcing member is calculated in compliance with a distance between the adjacent columnar supporting parts, and having regard to easiness of filling of the sealing resin 106 between the first semiconductor chip 102 and the columnar supporting parts 122. For example, in the example of FIG. 11, a reinforcing member 123a is added between the columnar supporting parts 122a and 122b, and 123b is added between the columnar supporting parts 122f and 122g.

In this manner, the bottom surface of the protruding portion of the second semiconductor chip 103 is supported by the plurality of columnar supporting parts 122 which were reinforced by adding reinforcing members between the columnar supporting parts, as the seat of the second semiconductor chip 103, it is possible to mount the second semiconductor chip 103 with ensuring stability

(Eighth Implementation Mode)

Next, an eighth implementation mode of the invention will be explained.

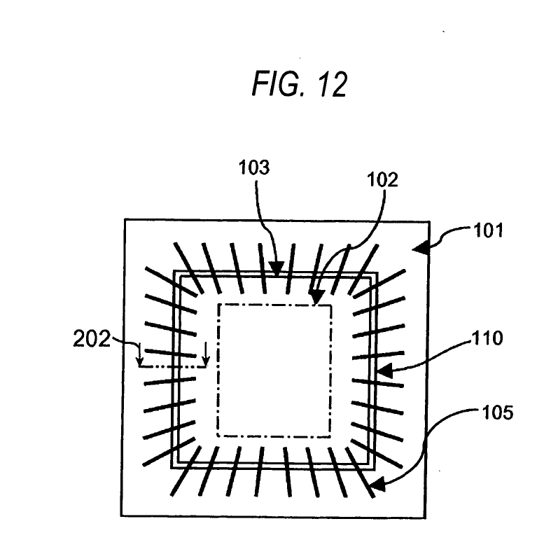

FIG. 12 is a schematic plan view of a semiconductor apparatus which relates to the eighth implementation mode, and a substantial part cross-section view which explains a shape of cross section of a 202 portion of FIG. 12.

This implementation mode is of a similar configuration to the first implementation mode, and a shape of cross section of the convex supporting part 110 on the upper surface of the circuit substrate 101, which is its different portion, will be explained.

In the semiconductor apparatus of the implementation mode, as shown in FIG. 12, curved surface parts 130, 131 are formed on a corner part of an upper end of the convex supporting part 110 which is the seat of the second semiconductor chip 103, and thereby, stress concentration at the time of bonding impact shock, of the second semiconductor chip 103 is avoided, and it is possible to mount the second semiconductor chip 103 stably.

Also, as a modified example of the eighth implementation mode, in case that the convex supporting part 110 on the upper surface of the circuit substrate 101, which is the seat of the second semiconductor chip 103, is located inside the bonding electrodes of the second semiconductor chip 103, it would be also fine if the second semiconductor chip 103 is mounted with ensuring stability of the second semiconductor chip 103, by the convex supporting part 110 on the upper surface of the circuit substrate 101, in which only the curved surface part 130, which is located outside the convex supporting part 110 on the upper surface of the circuit substrate 101, is formed, and an inside is of a corner left.

Also, in case that the convex supporting part 110 on the upper surface of the circuit substrate 101, which is the seat of the second semiconductor chip 103, is located outside the bonding electrodes of the second semiconductor chip 103, it becomes a reversed configuration.

(Ninth Implementation Mode)

Next, a ninth implementation mode of the invention will be explained.

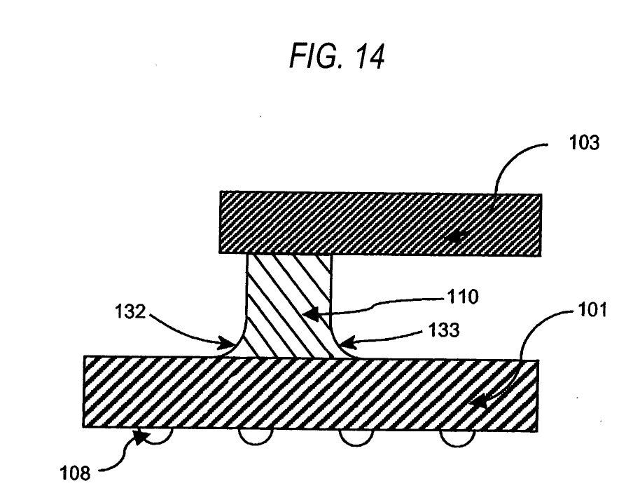

FIG. 14 is a substantial part cross-section view of a semiconductor apparatus which relates to the ninth implementation mode, and a thing which explains a shape of cross section of a portion of 202 of FIG. 12.

This implementation mode is of a similar configuration to the first implementation mode, and a shape of cross section of the convex supporting part 110 on the upper surface of the circuit substrate 101, which is its different portion, will be explained.

In the semiconductor apparatus of the implementation mode, as shown in FIG. 14, curved surface parts 132, 133 are formed on a root part of the convex supporting part 110, which is the seat of the second semiconductor chip 103, and the circuit substrate 101, and un-filling of sealing resin 106 is prevented, and it is possible to mount the second semiconductor chip 103 stably.

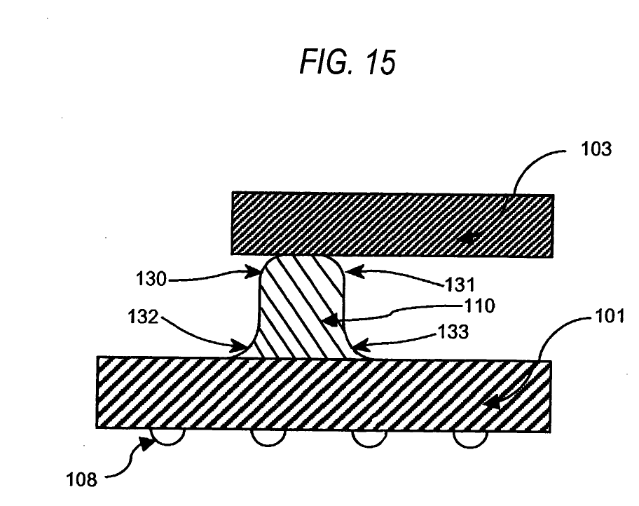

Also, as a modified example of the eighth and ninth implementation modes, as shown in a substantial part cross-section view of FIG. 15, it is possible to mount the second semiconductor chip 103, by the convex supporting part 110 in which the curved surface parts 130, 131 were formed on corner parts of an upper end of the convex supporting part 110, and the curved surface parts 132, 133 were formed on the root part of the convex supporting part 110, all together.

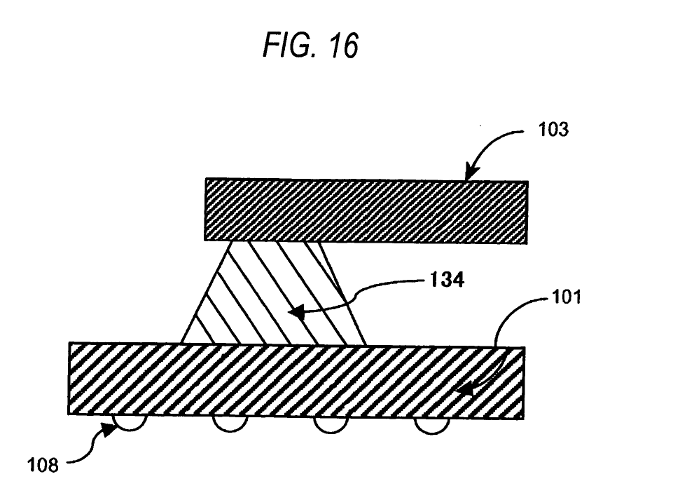

Also, as a further modified example of the eighth and ninth implementation modes, it would be also fine if the convex supporting part 110_is made as a trapezoid shaped supporting part 134, a width of which becomes narrower toward an upper part, as shown in the substantial part cross-section view of FIG. 16.

(Tenth Implementation Mode)

Next, a tenth implementation mode will be explained.

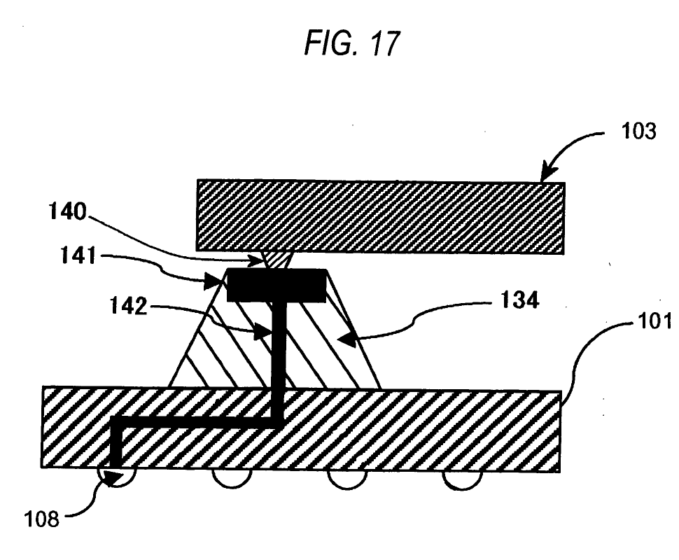

FIG. 17 is a substantial part cross-section view of a semiconductor apparatus which relates to the tenth implementation mode, and a thing which explains a shape of cross section of a portion of 202 of FIG. 12.

The semiconductor apparatus of the implementation mode is, as shown in FIG. 17, equipped with a bump connection part 141 on an upper part of the supporting part 134, and electrically connected to a projection electrode 140 of the second semiconductor chip 103 which is in a flip chip state.

This bump connection part 141 and the external terminal 108 on the bottom surface of the circuit substrate 101 are connected by an electric wiring 142 which was disposed in an inside of the supporting part 134 and an inside of the circuit substrate 101.

In this manner, the supporting part 134 becomes such a configuration that it supports the second semiconductor chip 103 which is larger than the first semiconductor chip 102, and at the same time, electrically connects the second semiconductor chip 103 in a flip chip state.

In this case, wiring bonding becomes unnecessary to the second semiconductor chip 103, which can more mitigate chip restrictions at the time of mounting.

Meanwhile, it would be also fine if a shape of the supporting part 134 on the upper surface of the circuit substrate 101 in the semiconductor apparatus of this implementation mode is not a trapezoid.

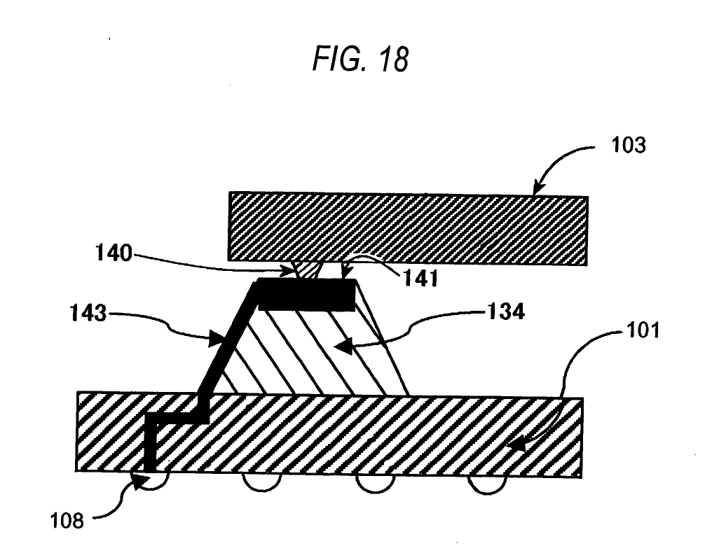

Also, a substantial part cross-section view of a modified example of the tenth implementation mode will be shown in FIG. 18.

In this modified example, as shown in FIG. 18, the bump connection part 141 and the external terminal 108 on the bottom surface of the circuit substrate 101 are connected by an electric wiring 143 which was disposed on a surface of the supporting part 134 and in an inside of the circuit substrate 101.

(Eleventh Implementation Mode)

Next, an eleventh implementation mode of the invention will be explained.

A semiconductor apparatus of this implementation mode is of such a case that three pieces of semiconductor chips are packed in one package.

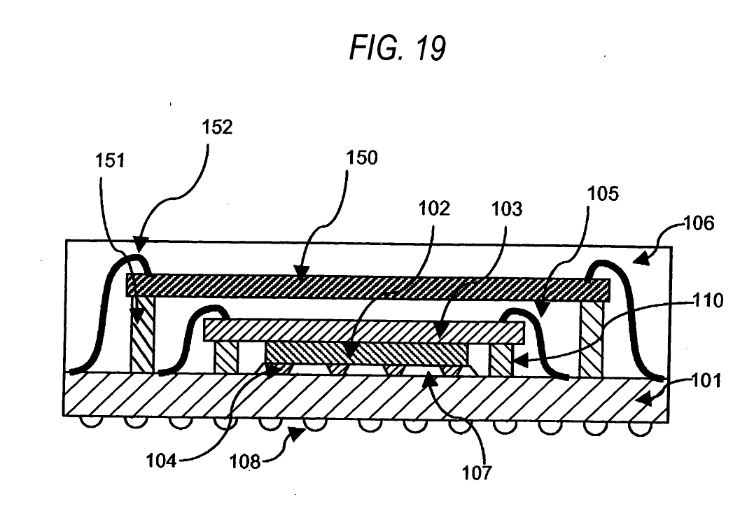

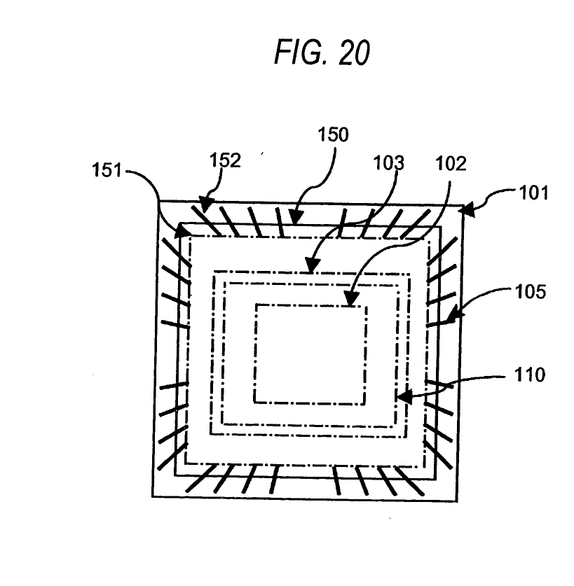

FIG. 19 is a schematic cross-section view of the semiconductor apparatus which relates to the eleventh implementation mode of the invention, and FIG. 20 is its schematic plan view.

As shown in FIG. 19 and FIG. 20, in case of a configuration of the second semiconductor chip 103 which is larger than the first semiconductor chip 102, and a third semiconductor chip 150 which is larger than the second semiconductor chip 103, convex_supporting parts 110, 151 on the upper surface of the circuit substrate 101 are formed double.

A mode until the second semiconductor chip 103 is mounted is as explained in the implementation modes 110.

The supporting part 151 on the upper surface of the circuit substrate 101, which is the seat of the third semiconductor chip 150, is adjusted in height so as not to be in contact with the metal thin wire 105 of the second semiconductor chip 103, and so as to be able to carry out filling of the sealing resin 106 between the second semiconductor chip 103 and the third semiconductor chip 150.

Meanwhile, 152 in the figure designates a metal thin wire which is an electric conductive thin wire for electrically connecting the third semiconductor chip 150 to the circuit substrate 101.

Meanwhile, this invention is a thing which is applicable to a semiconductor apparatus of such a type that a plurality of semiconductor chips were laminated and accommodated in one package, and in case that four or more semiconductor chips were packed in one package, it would be fine if the supporting parts are formed more, in compliance with the number of semiconductor chips.

A semiconductor apparatus which relates to the invention has a supporting part on a circuit substrate and the supporting part and the circuit substrate are integrated as one portion, and is useful as high-density packaging etc. due to lamination of semiconductor chips. Also, it is applicable to use applications such as module packaging.

1. A semiconductor apparatus comprising:
a circuit substrate;
a first semiconductor chip flip-chip-bonded on the circuit substrate;
a second semiconductor chip laminated on the first semiconductor chip, the second semiconductor chip being connected to the circuit substrate by an electric conductive wire and being larger than the first semiconductor chip so that the second semiconductor chip is protruded from at least one side of the first semiconductor chip as a protruding portion; and
a convex supporting part to support the protruding portion from bottom surface of the second semiconductor chip, the convex supporting part being integrated with the circuit substrate as one portion.

2. The semiconductor apparatus according to claim 1, wherein the second semiconductor chip is protruded from all sides of the first semiconductor chip and the convex supporting part supports the protruding portion formed at the all sides of the second semiconductor chip.

3. The semiconductor apparatus according to claim 2, wherein the convex supporting part supports outer edges of the second semiconductor chip

4. The semiconductor apparatus according to claim 1, wherein the convex supporting part supports a part of the protruding portion of the second semiconductor chip.

5. The semiconductor apparatus according to claim 1 further comprising:
a bond electrode formed on the second semiconductor chip, the bonding electrode connected to the circuit substrate by the electric conductive wire,
wherein the convex supporting part supports the protruding portion from bottom surface of the second semiconductor chip below the bonding electrode.

6. The semiconductor apparatus according to claim 1, wherein the second semiconductor chip has a protruding portion protruding from the first semiconductor by a certain value and the convex supporting part only supports the protruding portion protruding from the first semiconductor by the certain value.

7. The semiconductor apparatus according to claim 1, wherein a center of the second semiconductor chip is disposed with shifting a certain distance from a center of the first semiconductor chip.

8. The semiconductor apparatus according to claim 7, wherein the second semiconductor chip has a protruding portion protruding from the first semiconductor by a certain value and the convex supporting part only supports the protruding portion protruding from the first semiconductor by the certain value.

9. The semiconductor apparatus according to claim 1, wherein the convex supporting part includes a plurality of columnar supporting parts and each of the plurality of columnar supporting parts supports the protruding portion.

10. The semiconductor apparatus according to claim 9, wherein the plurality of columnar supporting parts are disposed non-uniformly at a periphery of the second semiconductor chip.

11. The semiconductor apparatus according to claim 9, wherein columnar supporting parts of the plurality of columnar supporting parts are formed at even intervals along one side of the second semiconductor chip.

12. The semiconductor apparatus according to claim 9, wherein a reinforcing member is disposed at such a place that a distance between any adjacent ones of the plurality of columnar supporting parts is a certain distance or more.

13. The semiconductor apparatus according to claim 1, wherein the convex supporting part has a curved surface part on its upper end corner.

14. The semiconductor apparatus according to claim 1, wherein the convex supporting part has a curved surface part on its root part.

15. The semiconductor apparatus according to claim 1, wherein the convex supporting part is of a trapezoid, a width of which becomes narrower toward an upper part.

16. The semiconductor apparatus according to claim 1 further comprising:
a third semiconductor chip laminated on the second semiconductor chip, the third semiconductor chip being connected to the circuit substrate by a second electric conductive wire and being larger than the second semiconductor chip so that the third semiconductor chip is protruded from at least one side of the second semiconductor chip as a second protruding portion;
a supporting part for supporting the second protruding portion from bottom surface of the third semiconductor chip, the supporting part being integrated with the circuit substrate as one portion.

17. A semiconductor apparatus comprising:
a circuit substrate;
a first semiconductor chip flip-chip-bonded on the circuit substrate;
a second semiconductor chip laminated on the first semiconductor chip, the second semiconductor chip being connected to the circuit substrate through a projection electrode formed on a bottom surface of the second semiconductor chip and being larger than the first semiconductor chip so that the second semiconductor chip is protruded from at least one side of the first semiconductor chip as a protruding portion;
a convex supporting part for supporting the protruding portion from bottom surface of the second semiconductor chip, the convex supporting part being integrated with the circuit substrate as one portion;
a bump connection part formed on the convex supporting part, the bump connection part connected to the projection electrode;
an external terminal formed on a bottom surface of the circuit substrate; and
an electric wiring connecting the projection electrode on the bottom surface of the second semiconductor chip to the external terminal thought the bump connection part formed on the convex supporting part.

18. The semiconductor apparatus according to claim 17, wherein the electric wiring includes a wiring passing through an inside of the convex supporting part.

19. The semiconductor apparatus according to claim 17, wherein the electric wiring includes a wiring formed along a surface of the convex supporting part.
